(19) United States
(12) Patent Application Publication
(10) Pub. No.: US 2016/0240718 A1
(43) Pub. Date: Aug. 18, 2016

(54) DOUBLE-PASS PHOTODIODE WITH EMBEDDED REFLECTOR

(71) Applicant: FCI AMERICAS TECHNOLOGY LLC, Carson City, NV (US)

(72) Inventor: Wojciech GIZIEWICZ, Berlin (DE)

(21) Appl. No.: 15/027,840

(22) PCT Filed: Oct. 9, 2014
(86) PCT No.: PCT/US2014/059857

§ 371 Date: Apr. 7, 2016

Related U.S. Application Data
(60) Provisional application No. 61/888,979, filed on Oct. 9, 2013.

(51) Int. Cl. H01L 31/105; H01L 31/18; H01L 31/0232

(52) U.S. Cl. CPC H01L 31/105; H01L 31/02327; H01L 31/184

(57) ABSTRACT

A photodiode, in particular photodiode for data transmission applications, can include a semiconductor substrate, which can also be referred to as a substrate layer, and a first semiconductor layer supported by, for instance arranged on, the semiconductor substrate. The photodiode can further include a second semiconductor layer supported by, for instance arranged on, the first semiconductor layer. The photodiode can further include an optical semiconductor mirror arranged between the semiconductor substrate and the first semiconductor layer such that when incident light passes through the second semiconductor layer and the first semiconductor layer along a first direction a first time, the incident light is reflected by the optical semiconductor mirror so as to pass through the first semiconductor layer a second time, which can also be referred to as a second pass. Thus, the photodiode can also be referred to as a double-pass photodiode.

### BACKGROUND

An important application of photodiodes is optical data transmission in which photodiodes are used in optical receivers to transform received light pulses that are modulated according to the data to be transmitted into electrical signals.

Photodiodes can comprise two contacting semiconductor layers being doped differently. In a process of doping a semiconductor, impurities can be intentionally introduced into the semiconductor such that its electrical characteristics are changed. In an n-doped semiconductor the impurities are electron donors that provide electrons, which may add to the electron conductivity of the semiconductor. In a p-doped semiconductor, the impurities are electron acceptors that add to the conductivity of the semiconductor by providing electron holes, which may move through the semiconductor.

Typically one layer of a photodiode is n-doped, and another layer is p-doped, thereby creating a p-n junction. A depletion region is naturally formed across the p-n junction in which all free charge carriers diffuse away due to a concentration gradient of electrons and holes, which creates an electric field across the depletion region. When a photon having sufficient energy hits the diode, the photon excites an electron, thereby creating a free electron and a positively charged electron hole. If the absorption occurs in, or near (e.g., one diffusion length away), the depletion region of the p-n junction, the carriers are swept from the junction by the electric field of the depletion region. Thus, holes move toward the anode, and electrons move toward the cathode, thereby producing a photocurrent. The resulting photocurrent is proportional to the intensity of the incident light opera large order of magnitude. Thus, light pulses can be transformed, by means of a photodiode, into electrical pulses.

For high-speed data transmission applications, PIN photodiodes can be used. The PIN photodiodes can have a wide, lightly doped (e.g., almost intrinsic) semiconductor region between the p-type semiconductor and the n-type semiconductor layer. Due to the intrinsic region, PIN photodiodes can allow for faster switching as compared to other diodes. Thus, PIN diodes can have a higher bandwidth as compared to conventional photodiodes.

When designing photodiodes for data transmission applications, one may try to meet objectives that typically compete with each other such as, for example, high bandwidth and high efficiency. The bandwidth of a photodiode can set an upper limit for the data rates that can be achieved when the photodiode acts as an optical receiver. The bandwidth depends on the duration of the photocurrent pulse from an electron hole pair that is created by an incident photon (the response time). The efficiency of a photodiode is the ratio of the generated photocurrent to incident light power. The efficiency is dependent on the wavelength of the incident light on the photodiode. The efficiency can also be expressed as a quantum efficiency, which is the ratio of the number of photo-generated charge carriers to the number of incident photons.

Bandwidth and efficiency are typically competing design goals in the sense that improving one usually degrades the other. For example, increasing the size of an active (photo-generating) region of a photodiode to improve efficiency results in an increased response time, and thereby results in lower bandwidth. Conversely, increasing the bandwidth by reducing the size of the active region results in lower efficiency.

In order to improve both bandwidth and efficiency, resonant cavity enhanced (RCE) photo detectors are known. In RCE photo detectors, a photodiode is arranged inside a Fabry-Perot resonant cavity. The effect of the optical cavity is to enhance the optical field due to resonance, thereby enabling the photo diode to be made thinner and therefore faster, while simultaneously increasing the quantum efficiency at the resonant wavelengths. RCE photo detectors have a disadvantage in that they are typically complex to manufacture, for example, due to the additional optical resonator that includes reflecting surfaces that must be accurately aligned. Furthermore, RCE photo detectors comprise high wavelength selectivity due to the resonant cavity, which can be disadvantageous in some data transmission applications that require relatively broad wavelength sensitivity.

In U.S. Pat. No. 6,023,485, a vertical cavity surface emitting laser (VCSEL) array with an integrated photodetector is disclosed. The disclosed photodetector is a PIN photodiode sharing a distributed Bragg reflector (DBR) with the VCSEL being arranged on top of the photodiode. This photodiode is not suitable as a receiver in data transmission applications due to the VCSEL and DBR mounted on top of the photodiode so as to block the photodiode.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

According to an embodiment, a photodiode, in particular a photodiode for data transmission applications, includes a semiconductor substrate, which can also be referred to as a substrate layer, and a first semiconductor layer supported by, for instance arranged on, the semiconductor substrate. The photodiode can further include a second semiconductor layer supported by, for instance arranged on, the first semiconductor layer. The photodiode can further include an optical semiconductor mirror arranged between the semiconductor substrate and the first semiconductor layer such that when incident light passes through the second semiconductor layer and the first semiconductor layer along a first direction a first time, the incident light is reflected by the optical semiconductor mirror so as to pass through the first semiconductor layer a second time, which can also be referred to as a second pass. Thus, the photodiode can also be referred to as a double-pass photodiode.

In accordance with another embodiment, a method for manufacturing a photodiode, for instance a photodiode that can be used in data transmission applications, can include providing a semiconductor substrate and forming a first semiconductor layer such that the first semiconductor layer is supported by, for instance arranged on, the semiconductor substrate. The method can further include arranging a second semiconductor layer such that the second semiconductor layer is supported by, for instance arranged on, the first semiconductor layer. The method can further include arranging an optical semiconductor mirror between the semiconductor substrate and the first semiconductor layer such that when incident light passes through the second semiconductor layer and the first semiconductor layer along a first direction, the incident light is reflected by the optical semiconductor mirror so as to pass through the first semiconductor layer a second time. A distributed Bragg reflector (DBR) can be grown on the substrate to form the semiconductor mirror, for instance, by growing alternating layers of AlAs and AlGaAs. Subsequently, a standard photodiode or PIN photodiode structure can be grown on the DBR. The method can include the step of doping (e.g., n-doping) the semiconductor mirror using doping techniques, such as vapor-phase epitaxy for example.

### BRIEF DESCRIPTION OF THE DRAWINGS

The foregoing summary, as well as the following detailed description of an example embodiment, are better understood when read in conjunction with the appended drawings. The invention is not limited, however, to the specific instrumentalities shown in the drawings. In the drawings:

FIG. 1 is a schematic cross section of a prior art photodiode;

FIG. 2 is a schematic cross section of a photodiode according to an embodiment;

FIG. 3 is a plot of modulation response versus modulation frequency of a measurement setup involving a prior art photodiode;

FIG. 4 is a plot of modulation response versus modulation frequency of another measurement setup involving a prior art photodiode with a logarithmic frequency scale;

FIG. 5 is a plot of the simulated photocurrent versus frequency of a prior art photodiode and a photodiode according to an embodiment;

FIG. 6 is a plot of absorption versus photon energy of a photodiode according to an embodiment; and

FIG. 7 is a table showing a comparison of characteristics of prior art photodiodes and photodiodes according to an embodiment.

### DETAILED DESCRIPTION OF ILLUSTRATIVE EMBODIMENTS

For convenience, the same or equivalent elements in the various embodiments illustrated in the drawings have been identified with the same reference numerals. Certain terminology is used in the following description for convenience only and is not limiting. The words “left,” “right,” “front,” “rear,” “upper,” and “lower” designate directions in the drawings to which reference is made. The words “forward,” “forwardly,” “rearward,” “inner,” “inward,” “inwardly,” “outer,” “outward,” “outwardly,” “upward,” “upwardly,” “downward,” and “downwardly” refer to directions toward and away from, respectively, the geometric center of the object referred to and designated parts thereof. The terminology intended to be non-limiting includes the above-listed words, derivatives thereof and words of similar import.

It is an object of an embodiment to provide a photodiode, for instance a photodiode for data transmission applications, that has a high bandwidth and high efficiency. The photodiode may also be simple to manufacture and cost efficient. Furthermore, the photodiode may provide for relatively broad wavelength sensitivity. These and other objects that will become apparent upon reading the following description may be solved by a photodiode according to the claims and a method of manufacturing the photodiode according to the claims, for example.

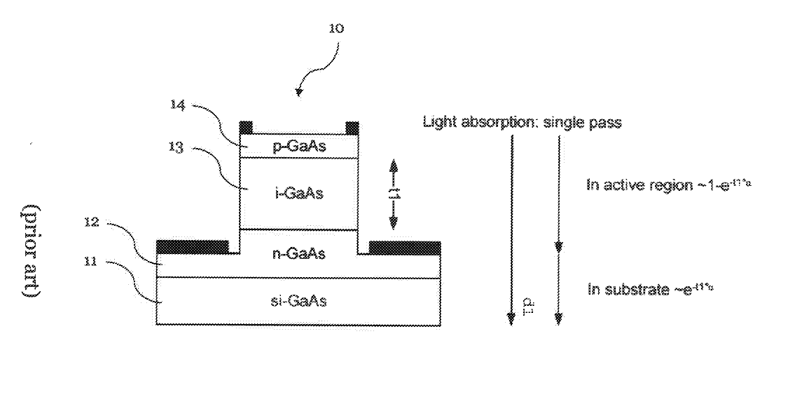

Referring initially to FIG. 1, a schematic cross section is shown of a prior art PIN-type photodiode 10, which is a photodiode that includes an intrinsic layer 13 between an n-doped layer 12 and a p-doped layer 14. The n-doped layer 12 is arranged on a substrate layer 11. The intrinsic layer 13 can be essentially undoped. As shown, the intrinsic layer can be arranged on the n-doped layer 12. Further, a p-doped layer 14 can be arranged on the intrinsic layer 13.

The photodiode 10 defines an active region, which can be a region in which photoabsorption results in a measurable amount. The active region defines a thickness t₁ along a first direction d₁ such that the light absorption in the active region is proportional to 1−exp(−t₁α), where α is a parameter that depends on the material and the energy of the incident light. Accordingly, the light absorption in the substrate layer 11 is proportional to exp(−t₁α). Thus, the larger the thickness t₁ the more light can be absorbed in the active region, which results in a higher efficiency. However, as mentioned above, the larger thickness t₁ can result in a lower transit time of the photodiode 10 and, thus, low bandwidth. Consequently, there can be a trade-off in conventional photodiodes, such as the photodiode 10 for example, between sensitivity and transit time.

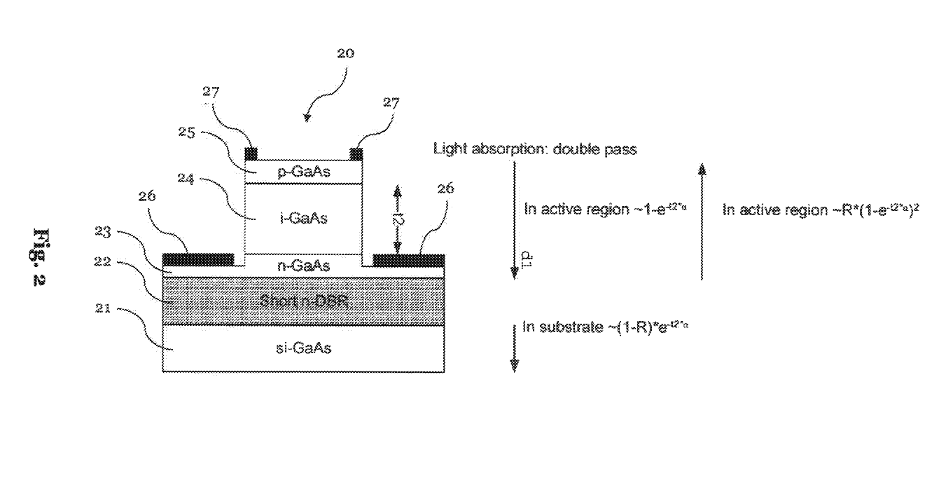

Referring now to FIG. 2, a schematic cross section of a PIN-type photodiode 20 is shown according to an example embodiment. The photodiode 20 can include a semiconductor substrate 21, which can also be referred to as a substrate layer 21, and a first semiconductor layer 23 supported by, for instance arranged on, the semiconductor substrate 21. The photodiode 20 can further include a second semiconductor layer 25 supported by, for instance arranged on, the first semiconductor layer 23. The photodiode 20 can further include an optical semiconductor mirror 22 arranged between the semiconductor substrate 21 and the first semiconductor layer 23 such that when incident light passes through the second semiconductor layer 25 and the first semiconductor 23 layer along the first direction d₁ a first time, the incident light is reflected by the optical semiconductor mirror 22 so as to pass through the first semiconductor layer 23 a second time, which can also be referred to as a second pass. Thus, the photodiode 20 can also be referred to as a double-pass diode 20. In contrast to the photodiode 10 of FIG. 1, the semiconductor mirror 22 can be arranged between the substrate layer 21 and the first semiconductor layer 23. Further, the photodiode 20 can include an intrinsic layer 24 that can be essentially undoped and can be supported by, for instance arranged on, the first semiconductor layer 23, which can be n-doped and thus can also be referred to as an n-doped layer 23. The second semiconductor layer 25, which can be p-doped and thus can also be referred to as a p-doped layer 25, can be supported by, for instance arranged on, the intrinsic layer 24. The intrinsic layer 24 can have a density of impurities that is lower than that of the first and second semiconductor layers 23 and 25. Thus, the intrinsic layer 24 can be referred to as being essentially undoped. For instance, the intrinsic layer 24 can be formed from an essentially undoped semiconductor material. The reflected light can pass at least through a portion of the intrinsic layer 24. Thus, the light may reach the active region a second time and the sensitivity of the photodiode 20 may be increased as compared to a conventional photodiode, for instance the photodiode 10.

As described above, the semiconductor mirror 22 can be n-doped, and thus can be fabricated with a lower resistance than a p-doped semiconductor mirror, which can improve the speed of the photodiode. Likewise compositional grading and/or modulated doping may be used between respective mirror layers to decrease energy band offset and thereby decrease resistance. Additionally, because photodiodes are generally used in reverse bias, it can be advantageous in certain applications to use a common mirror layer acting as the n-type contact for multiple, for instance all, photodiodes in an array or matrix.

According to an example embodiment, the semiconductor mirror 22 between the semiconductor substrate 21 and the first semiconductor layer 23 is the only mirror in the photodiode 20. Thus, there is no second mirror arranged on or above the second semiconductor layer 25 along the first direction d₁ in accordance with the aforementioned embodiment.

The photodiode 20 defines an active region, which can be a region in which photoabsorption results in a measurable amount. The active region of the photodiode 20 defines a thickness t₂ along the first direction d₁ such that light absorption in the active region is proportional to 1−exp(−t₂α), where α is a parameter that depends on the material and the energy of the incident light. Light that is incident on the photodiode 20 can be reflected by the semiconductor mirror 22 so as to define reflected light. The reflected light, and thus the reflection, can be characterized by a reflection coefficient that indicates an intensity of the reflected light relative to the light incident on the semiconductor mirror 22. Due to the reflection of the incident light by the semiconductor mirror 22, an absorption of the reflected light in the active region during the second pass of the light through the active region can be proportional to R·(1−exp(−t₂α))². Accordingly, the light absorption in the substrate 21 can be proportional to (1−R)·exp(−t₂α).

Therefore, as compared to the photodiode 10, less light is absorbed in the substrate layer 21 of the photodiode 20, and more light can be absorbed in the active region of the photodiode 20 because light is absorbed during a first pass (from the incident light) and the second pass (from the reflected light). Thus, light from the first pass and the second pass can be aggregated to define the total light that is absorbed in the active region. By way of example, when the reflection coefficient is 1, none of the incident light is absorbed in the substrate 21 and all of the light is reflected back into the active region. But when the coefficient is less than 1 for instance 0.9, a first fraction of the incident light is absorbed by the substrate 21 and a second fraction that is greater than the first fraction is reflected back into the active region. In some cases, the semiconductor mirror 22 does essentially not absorb light or only absorbs a small, negligible fraction of the incident light, thereby reflecting most of the incident light through the first and second semiconductor layers 23 and 25 to allow for a second absorption of light in the active region of the photodiode 20, and thus only a small fraction of the incident light is transmitted to and absorbed in the substrate layer 21.

As shown, the photodiode 20 is gallium arsenide (GaAs) based, which can enable high switching frequencies and low noise applications, though it will be understood that the photodiode 20 can be formed by other types of semiconductor materials as desired, such as silicon based semiconductor materials for example. Furthermore, as shown, the photodiode 20 is a PIN-type photodiode that includes the intrinsic layer 24. The intrinsic layer 24 can be formed from an essentially undoped semiconductor material such that the density of impurities in the intrinsic layer 24 are much lower than that of the first and second semiconductor layers 23 and 25. The intrinsic layer 24 can allow for faster switching and can result in a higher bandwidth as compared to photodiodes without an intrinsic layer. It will be understood, however, that the photodiode 20 can be constructed without an intrinsic layer.

Still referring to FIG. 2, the photodiode 20 can include one or more electrical contacts 26 that can be disposed on the first semiconductor layer 23. The photodiode 20 can further include one or more electrical contacts 27 that can be disposed on the second semiconductor layer 25. The electrical contacts 26 and 27 can be used to discharge photocurrent that is generated. For instance, the photodiode 20 can be electrically connected to electronic circuitry, for instance one or more amplifiers, via the electrical contacts 26 and 27. The electrical contacts 26 and 27 can be made from any electrically conductive material as desired, such as, for example, copper, gold, or an alloy thereof. The electrical contacts 26 and 27 can be applied to the respective semiconductor layers during the growth process of the respective semiconductor crystal of the photodiode 20 or can be applied subsequent to the growth using any appropriate bonding technique as desired.

As shown, the optical semiconductor mirror 22 of the photodiode 20 is a distributed Bragg reflector (DBR), though it will be understood that the photodiode 20 can include alternative mirrors as desired. The DBR can define multiple layers along the first direction d₁ such that the layers alternate between having a high refractive index and a low refractive index along the first direction. For instance, in accordance with an example embodiment, the DBR includes alternating layers of aluminum arsenide (AlAs) and aluminum gallium arsenide (AlGaAs). The DBR can be integrated into the photodiode 20 by a conventional crystal growth process such as epitaxy for example. The layers of the semiconductor mirror 22, for instance the DBR, can be grown on the substrate 21 before the growth of a standard photodiode or PIN photodiode structure. For example, the DBR can be formed from alternating layers of aluminum arsenide (AlAs) and aluminum gallium arsenide (AlGaAs). AlAs and AlGaAs have almost equal lattice constants, making it possible to efficiently grow layers of one on the other one. The lattice constant, or lattice parameter, refers to the constant distance between unit cells in a crystal lattice. In accordance with one example embodiment, the semiconductor mirror 22, and in particular the DBR, can include between 8 and 12 pairs, for instance 10 pairs, of AlAs and AlGaAs layers.

In accordance with an example embodiment, the photodiode 20, and in particular the DBR of the photodiode 20, may be composed of alternating layers of AlAs and AlGaAs such that the AlGaAs layers have sufficient Al content so that their band gap is larger than the energy of photons associated with wavelength range for which the photodiode is sensitive. For example, in some cases, the Al content of the AlGaAs layers can be greater than 10%, for instance at least 12%. Al content of at least 12% can result in a sufficient band gap for a typical 850 nm application in accordance with one example embodiment.

The DBR can comprise between 8 and 12 pairs of AlAs/AlGaAs-layers. It has been found by the originators of this disclosure that such a number of reflector pairs is sufficient to achieve a reflectivity of 80%-90% which leads to the advantageous effects described above. Furthermore, this number of reflector pairs allows for a relatively thin DBR structure, resulting in only a minor increase of crystal growth thickness and therefore negligible manufacturing costs. For example, the DBR can comprise ten pairs of AlAs and AlGaAs-layers.

The optical semiconductor mirror 22 can define a reflectivity from about 80% to about 90%. It has been found herein that this range of reflectivity can be sufficient to obtain one or more advantageous effects of the embodiments described herein. It will be understood that the photodiode 20, and in particular the semiconductor mirror 22, can be constructed so as to define other reflectivities as desired. In an example embodiment in which the mirror 22, and in particular the DBR, includes alternating AlAs and AlGaAs layers on a GaAs substrate, approximately 10 pairs of the alternating layers, which can also be referred to as reflector pairs, can achieve a reflectivity between 80% and 90%.

The semiconductor mirror 22 can be doped, for instance highly doped, to improve the conductivity of the photodiode 20. In one example embodiment, the doping concentration of the semiconductor mirror 22 is about at least about 10¹⁸ cm⁻³ to provide a necessary conductivity of the photodiode 20. In accordance with the illustrated embodiment, the semiconductor mirror 22 can be n-doped to include free electrons as charge carriers, which can achieve a greater mobility than electron holes that are provided by p-doped semiconductors, though it will be understood that the semiconductor mirror 22 can be p-doped as desired in accordance with alternate embodiments. The semiconductors can be doped using standard semiconductor doping techniques such as, for example, vapor-phase epitaxy, wherein a gas containing the negative dopant is passed over the substrate wafer. By way of an example in which a GaAs is n-doped, hydrogen sulfide can be passed over the gallium arsenide, and sulfur can be incorporated into the structure. In an example embodiment, the doping concentration of the first and second semiconductor layers 23 and 25 can be between about 10¹⁷ to 10¹⁸ cm⁻³.

In some cases, less than 10%, fur instance less than 5%, of the incident light is absorbed by the semiconductor substrate 21. Thus, the photodiode 20, and in particular the optical semiconductor mirror 22, can define a photo absorption that is less than 5% such that less than 5%, for instance a fraction of 5%, of the incident light along the first direction d₁ is absorbed in the substrate 21. Such a low photo absorption in the substrate 21 can avoid a slow diffusion of charge carriers in the substrate 21. Further, the semiconductor substrate 21 can be semi-insulating (si), which can minimize parasitic capacitance effects with photodiode contact pads.

An example method for manufacturing a photodiode, for instance the photodiode 20 that can be used in data transmission applications, can include providing the semiconductor substrate 21 and forming the first semiconductor layer 23 such that the first semiconductor layer is supported by, for instance arranged on, the semiconductor substrate 21. The method can further include arranging the second semiconductor layer 25 such that the second semiconductor layer 25 is supported by, for instance arranged on, the first semiconductor layer 23. The method can further include arranging the optical semiconductor mirror 22 between the semiconductor substrate 21 and the first semiconductor layer 23 such that when incident light passes through the second semiconductor layer 25 and the first semiconductor layer 23 along the first direction d₁, the incident light is reflected by the optical semiconductor mirror 22 so as to pass through the first semiconductor layer 23 a second time. The method of manufacturing the photodiode 20 can be based on epitaxy. For instance, a crystalline overlayer can be deposited on a crystalline substrate (e.g., GaAs) such that there is registry between the overlayer and the substrate. A distributed Bragg reflector (DBR) can be grown on the substrate to form the semiconductor mirror 22, for instance, by growing alternating layers of AlAs and AlGaAs. Subsequently, a standard photodiode or PIN photodiode structure can be grown on the DBR. The method can include the step of doping (e.g., n-doping) the semiconductor mirror 22 using doping techniques, such as vapor-phase epitaxy for example.

The first semiconductor layer 23 can be directly grown on the semiconductor mirror 22 during a crystal growth. Further, the second semiconductor layer 25 can be directly grown on the first semiconductor layer 23 during a crystal growth. Further, the entire photodiode 20 can be grown in a single process in accordance with one embodiment. Further still, the entire photodiode 20 can be grown in a single epitaxy process. Thus, any additional costs of integrating the semiconductor mirror 22 into the photodiode 20 can be minimal.

The method of manufacturing the photodiode 20 can further include arranging the intrinsic layer 24 between the first semiconductor layer 23 and the second semiconductor layer 25. The intrinsic layer 24 can be formed from an essentially undoped semiconductor such that the essentially undoped semiconductor defines a density of impurities that is lower than the density of impurities associated with the first and second semiconductor layers 23 and 25.

In one embodiment, the method further includes the step of forming the semiconductor mirror 22 as a distributed Bragg reflector (DBR). The DBR, which can be composed of alternating layers with high and low refractive indexes, can be integrated into the photodiode 20 by a conventional crystal growth process such as epitaxy. In some cases, the layers of the DBR can be grown on the substrate before the growth of a standard photodiode or PIN photodiode structure. The method can further include growing the semiconductor mirror 22 on the semiconductor substrate 21 during crystal growth. Crystal growth, such as epitaxy for example, may allow for incorporating the semiconductor mirror 22 in the photodiode. The mirror 22 can be grown on the substrate 21 during a conventional photodiode growth process. In one embodiment, the method can further include n-doping the semiconductor mirror 22.

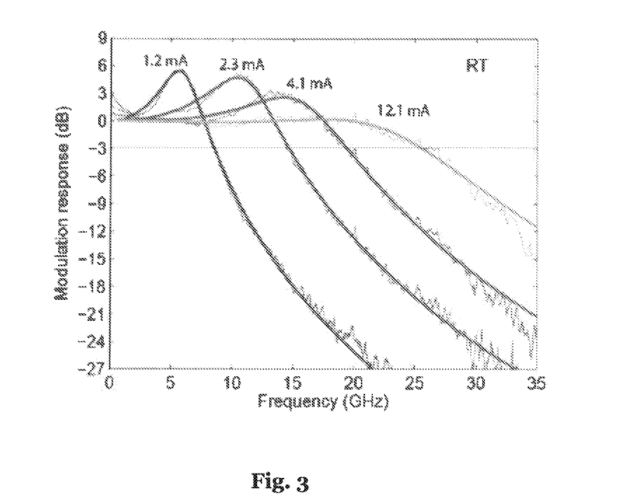

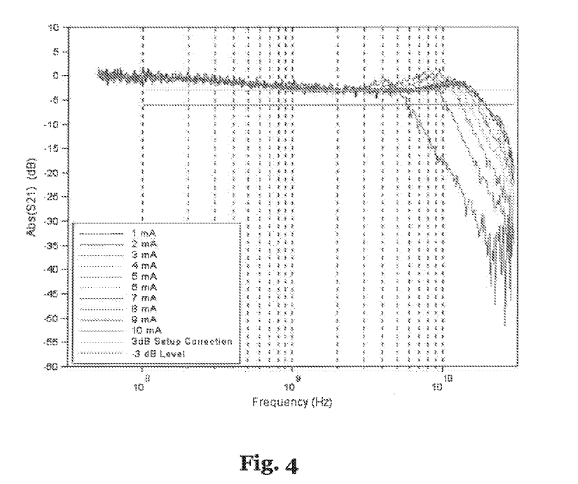

FIGS. 3 and 4 show measurement results obtained using a setup that includes prior art photodiodes to illustrate an example disadvantage that can be overcome by various embodiments of the photodiode 20. In the setup, a prior art photodiode is illuminated by pulsed light emitted from a vertical-cavity surface-emitting laser (VCSEL). FIG. 3 is based on data taken from the publication of Westburgh et al., IEEE Photonics Technology Letters, vol. 25 n. 8, 2013. In FIG. 3, the modulation response of the photodiode (in dB) is plotted against the modulation frequency (in GHz) of the incident light at different operating currents (in mA) of the laser diode. The modulation response shows an unexpected “bump” at low frequencies between 0 GHz and approximately 2 GHz before the expected frequency behavior of the laser diode is observed. It is recognized herein that this low-frequency (“DC”) behavior is not caused by the frequency characteristic of the laser diode, but is based on the photodiode used, and further can be explained by slow-tail effects due to charge carrier generation and diffusion in the substrate.

FIG. 4 shows a similar measurement with a different photodiode and different current levels as compared to FIG. 3. Due to the logarithmic frequency scale, the low frequency behavior between 0 GHz and approximately 2 GHz can be nicely seen as a rise of the modulation response with lower frequencies (DC). Again, it is recognized herein that this behavior can be caused by the photodiode and not by the VCSEL used in accordance with an example scenario.

As illustrated by FIGS. 3 and 4, there can be a mismatch between DC and HF modulation responses associated with prior art photodiodes. This can reduce the receiver sensitivity due to saturation of the receiver circuit (artificially low extinction ratio) or due to gain adjustment based on an average received intensity (effective optical modulation attenuation). By way of example, the above described behavior of photodiodes can be problematic in data transmission applications that use long coding schemes (e.g., 64b/66b) or uncoded data, and can result in vertical eye closure.

The example problems described above are not present when photodiodes, for instance the photodiode 20, according to various embodiments are used at least because there is essentially no absorption and a slow diffusion of slow charge carriers in the substrate 21. Furthermore, the HF sensitivity is increased because light is “recycled”, which enables increased absorption during the second pass through the active region of the photodiode 20.

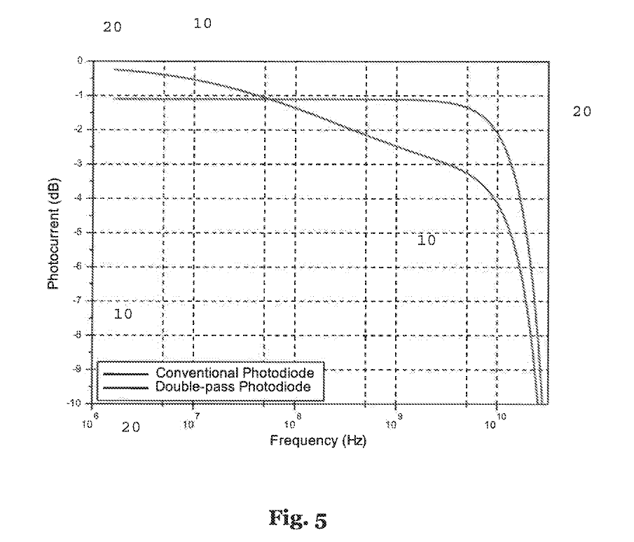

FIG. 5 illustrates the above-described characteristics of a photodiode constructed in accordance with an example embodiment, for instance the photodiode 20, as compared to the characteristics of a prior art photodiode, for instance the photodiode 10. Because of the reflectively of the photodiode 20, the photodiode 20 can also be referred to as a double-pass photodiode 20, as shown. Referring to FIG. 5, a simulated photocurrent (in dB) is plotted against a modulation frequency (in Hz). In accordance with the illustrated example, the photodiode 20 outperforms the prior art photodiode 10 at greater than about 5×10⁷ Hz, and in particular in the frequency regime which can generally be referred to as the high frequency regime.

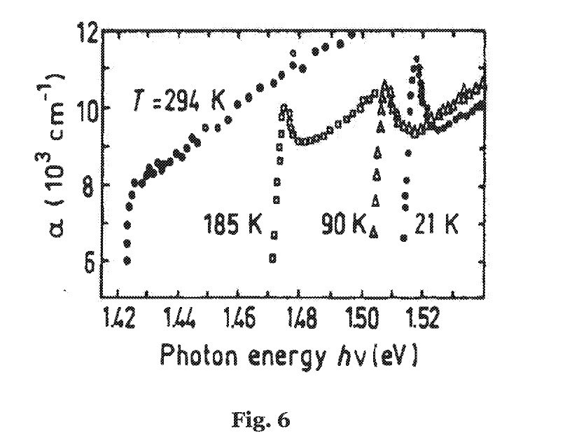

FIG. 6 shows an example plot of the absorption α (in 10³ cm⁻¹) versus the incident photon energy hν (in eV) at different temperatures (in K) of the photodiode 20 in accordance with an example embodiment. Referring to FIG. 6, the photodiode 20 can provide an excellent wavelength and temperature behavior, in particular at wavelengths beyond normal industry specifications, e.g., 865 nm (corresponding to approximately 1.43 eV). Also, while the absorption coefficient can vary in an example industrial range of 840 nm to 860 nm (corresponding to approximately 1.476 eV to 1.4417 eV) by 15% to 20%, there is essentially no wavelength dependence in sensitivity this range using the photodiode 20 according to the illustrated example.

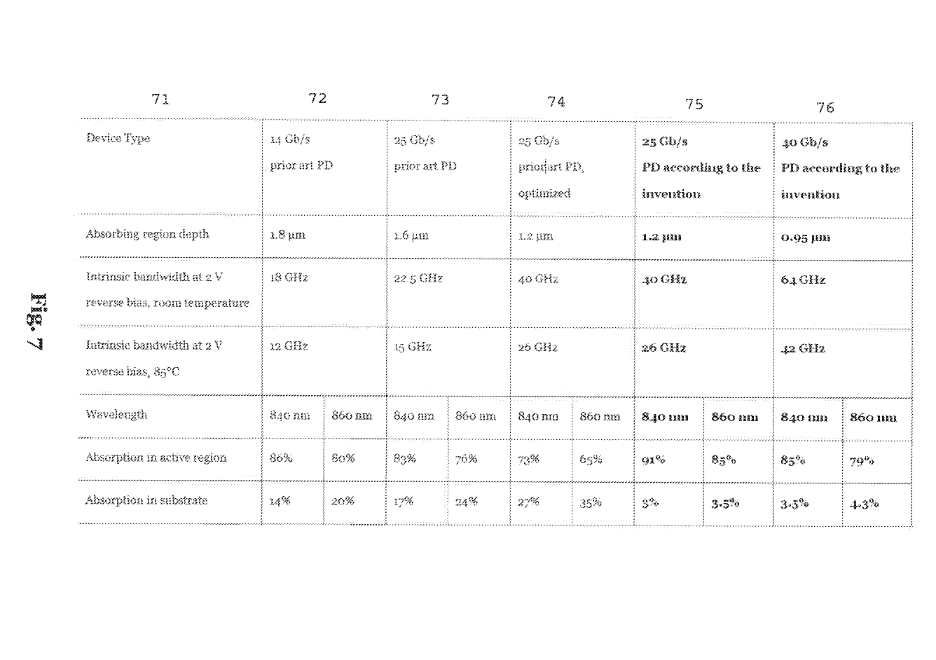

By way of example of high-speed data transmission applications, the table in FIG. 7 provides a comparison of prior art photodiodes, for instance the photodiode (PD) 10, against photodiodes according to various embodiments described herein, for instance the photodiode 20, that can be operated at different data rates (e.g., 14, 25 and 40 Gb/s). As shown in FIG. 7, the photodiodes according to various embodiments (represented by columns 75 and 76) provide for a higher absorption in the active region of the photodiode as compared to prior art photodiodes (represented in columns 72, 73, and 74). At the same time, the absorption in the substrate can be reduced to a low fraction, for instance a fraction between 3% and 4.3%.

Still referring to FIG. 7, and in particular the fourth column 74 of FIG. 7, characteristics of an optimized prior art photodiode are shown. The optimized prior art diode was designed to provide a higher intrinsic bandwidth at the cost of lower sensitivity, but has a conventional structure (same as the photodiode in the third column), for instance a structure like the photodiode 10. The parameters in the fifth column 75 are parameters of a photodiode according to an embodiment, but also based on the structure of the photodiode in the fourth column. In particular, the photodiode represented by the fifth column 75 has the same absorbing region depth and intrinsic bandwidth as the prior art device represented by the fourth column 74, but the photodiode represented by the fifth column 75 includes the optical semiconductor mirror 22. Thus, the photodiode according to the embodiment shows an improved sensitivity (not shown in the table) as compared to the prior art photodiode, which can be due to the effects of the semiconductor mirror 22 as described above.

The photodiodes, for instance the photodiode 20, according to this disclosure can provide for several advantages over prior art photodiodes, for instance the photodiode 10. For example, due to the arrangement of the semiconductor mirror 22 between the semiconductor substrate 21 and the first semiconductor layer 23, there can be substantially no photo absorption in the substrate 21 of the photodiode 20. The photo-creation of charge carriers in the substrate 21 can be avoided or at least reduced. In conventional photodiodes, such charge carriers may otherwise slowly diffuse in the substrate, add to the noise background, and decrease the response time and bandwidth of the photodiode. In photodiodes described herein, such slow substrate currents can be avoided or at least reduced.

When using the photodiode 20 in a data transmission application such as an optical receiver, the photodiode can improve the performance of the optical receiver by making the low frequency (DC) and high frequency (HF) sensitivity equal or at least similar to each other. This benefit is described in more detail above.

Another advantageous aspect of the present disclosure is the increase of sensitivity of the photodiodes described herein, for instance the photodiode 20, due to the second pass of the reflected light through the active (photo absorbing) region. Thus, light that would otherwise be lost in the substrate adds to the photo-creation of fast charge carriers in the p-n junction of the photodiode, thereby increasing the efficiency of the photodiode.

Yet another advantage of the photodiode 20 is an improvement in wavelength sensitivity. Unlike an RCE photo detector, the photodiode 20 is sensitive in a relatively broad wavelength range. For instance, the semiconductor mirror 22 between the substrate 21 and the first semiconductor layer 23 does not require such a sharp wavelength selectivity as the resonant cavity of a RCE photo detector requires.

The embodiments described in connection with the illustrated embodiments have been presented by way of illustration, and the present invention is therefore not intended to be limited to the disclosed embodiments. Furthermore, the structure and features of each the embodiments described above can be applied to the other embodiments described herein, unless otherwise indicated. Accordingly, the invention is intended to encompass all modifications and alternative arrangements included within the spirit and scope of the invention, for instance as set forth by the appended claims.

1. A photodiode comprising:
a semiconductor substrate;
a first semiconductor layer supported by the semiconductor substrate;
a second semiconductor layer supported by the first semiconductor layer; and
an optical semiconductor mirror arranged between the semiconductor substrate and the first semiconductor layer such that when incident light passes through the second semiconductor layer and the first semiconductor layer along a first direction a first time, the incident light is reflected by the optical semiconductor mirror so as to pass through the first semiconductor layer a second time.

2. The photodiode as recited in claim 1, wherein the optical semiconductor mirror is a distributed Bragg reflector (DBR).

3. The photodiode as recited in claim 2, wherein the DBR includes alternating layers of aluminum arsenide (AlAs) and aluminum gallium arsenide (AlGaAs).

4. The photodiode as recited in claim 3, wherein the DBR includes between 8 and 12 pairs of AlAs and AlGaAs layers.

5. The photodiode as recited in claim 1, wherein the optical semiconductor mirror is directly grown on the semiconductor substrate during a crystal growth.

6. The photodiode as recited in claim 1, wherein the optical semiconductor mirror defines a reflectively from about 80% to about 90%.

7. The photodiode as recited in claim 1, wherein the optical semiconductor mirror is n-doped.

8. The photodiode as recited in claim 1, wherein the semiconductor substrate defines a photo absorption that is less than 5%.

9. The photodiode as recited in claim 1, further comprising:
an intrinsic layer arranged between the first semiconductor layer and the second semiconductor layer such that the photodiode is a PIN photodiode.

10. The photodiode as recited in claim 1, wherein the photodiode is a gallium arsenide (GaAs) based photodiode.

11. The photodiode as recited in claim 1, wherein the first semiconductor layer is directly grown on the semiconductor mirror during a crystal growth.

12. The photodiode as recited in claim 1, wherein the second semiconductor layer is directly grown on the first semiconductor layer during a crystal growth.

13. A method for manufacturing a photodiode, the method comprising the steps of:
providing a semiconductor substrate;
forming a first semiconductor layer such that the first semiconductor layer is supported by the semiconductor substrate;
forming a second semiconductor layer;
arranging the second semiconductor layer such that the second semiconductor layer is supported by the first semiconductor layer; and
arranging an optical semiconductor mirror between the semiconductor substrate and the first semiconductor layer such that when incident light passes through the second semiconductor layer and the first semiconductor layer along a first direction a first time, the incident light is reflected by the optical semiconductor mirror so as to pass through the first semiconductor layer a second time.

14. The method as recited in claim 13, the method further comprising the step of forming the semiconductor mirror, wherein forming semiconductor mirror comprises forming a distributed Bragg reflector (DBR).

15. The method as recited in claim 14, wherein forming the DBR comprises forming alternating layers of aluminum arsenide (AlAs) and aluminum gallium arsenide (AlGaAs).

16. The method as recited in claim 13, wherein the method further comprises the step of growing the optical semiconductor mirror on the semiconductor substrate during a crystal growth.

17. The method as recited in claim 13, wherein the method further comprises the step of doping the optical semiconductor mirror so that the optical semiconductor mirror is n-doped.

18. The method as recited in claim 14, wherein the method further comprises the step of arranging an intrinsic layer between the first semiconductor layer and the second semiconductor layer.

19. The method as recited in claim 14, wherein the method further comprises the step of growing the first semiconductor layer directly on the semiconductor mirror during a crystal growth.

20. The method as recited in claim 15, wherein the method further comprises the step of growing the second semiconductor layer directly on the first semiconductor layer during a crystal growth.
